(19) United States
(12) Patent Application Publication
(10) Pub. No.: US 2013/0058009 A1
(43) Pub. Date: Mar. 7, 2013

(54) METAL CURRENT COLLECTOR, METHOD FOR PREPARING THE SAME, AND ELECTROCHEMICAL CAPACITORS WITH SAME

(71) Applicants: Hak Kwan Kim, Seoul (KR); Jun Hee Bae, Seoul (KR); Ho Jin Yun, Suwon (KR); Bae Kyun Kim, Seongnam (KR)

(72) Inventors: Hak Kwan Kim, Seoul (KR); Jun Hee Bae, Seoul (KR); Ho Jin Yun, Suwon (KR); Bae Kyun Kim, Seongnam (KR)

(73) Assignee: SAMSUNG ELECTRO-MECHANICS CO., LTD., Suwon (KR)

(21) Appl. No.: 13/480,046

(22) Filed: May 24, 2012

(30) Foreign Application Priority Data
Sep. 6, 2011 (KR) 10-2011-0090173

(51) Int. Cl. H05K 1/09; H01G 13/00; H01G 9/155; H05K 1/00; B05D 5/12; B82Y 99/00

(52) U.S. Cl. 361/502; 174/258; 174/257; 427/79; 216/17; 427/528; 977/948

(57) ABSTRACT

The present invention relates to a metal current collector including a metal substrate having grooves on a surface thereof, a carbon buffer layer formed on the metal substrate, and a conductive layer formed on the carbon buffer layer, a method for preparing the same, and electrochemical capacitors comprising the same. According to the present invention, a metal current collector including a metal substrate having grooves on a surface thereof, a carbon buffer layer formed on the metal substrate, and a conductive layer formed on the carbon buffer layer has a large surface area and low electrical resistance. This metal current collector can be effectively used in electrochemical capacitors with high capacity and high output characteristics by improving contact characteristics with an active material layer.

### CROSS-REFERENCE TO RELATED APPLICATIONS

Claim and incorporate by reference domestic priority application and foreign priority application as follows:

### “CROSS REFERENCE TO RELATED APPLICATION

This application claims the benefit under 35 U.S.C. Section 119 of Korean Patent Application Serial No. 10-2011-0090173, entitled filed Sep. 6, 2011, which is hereby incorporated by reference in its entirety into this application.”

### BACKGROUND OF THE INVENTION

1. Field of the Invention

The present invention relates to a metal current collector, a method for preparing the same, and electrochemical capacitors comprising the same.

2. Description of the Related Art

Conventional electrochemical capacitors can be classified roughly into a pseudocapacitor and an electric double layer capacitor (EDLC).

The pseudocapacitor uses a metal oxide as an electrode active material, and most studies use a ruthenium oxide, an iridium oxide, a tantalum oxide, and a vanadium oxide. However, this pseudocapacitor has a disadvantage that utilization of the electrode active material is reduced due to non-uniformity of potential distribution of a metal oxide electrode.

In case of the EDLC, currently, a porous carbon material with high electrical conductivity, high thermal conductivity, low density, suitable corrosion resistance, low coefficient of thermal expansion, and high purity is used as an electrode active material. However, in order to improve performance of the capacitor, many studies have been made on preparation of a new electrode active material, surface modification of the electrode active material, performance improvement of a separator and an electrolyte, and performance improvement of an organic solvent electrolyte for increasing the utilization and cycle life of the electrode active material and improving high rate charging and discharging characteristics.

In case of a currently studied capacitor, an aluminum or titanium sheet or an expanded aluminum or titanium sheet current collector is used as current collectors of both electrodes and in addition, various types of current collectors such as a punched aluminum or titanium sheet are used.

However, these current collectors have relatively high contact resistance with an electrode active material layer compared to a pure metal surface due to an oxide layer naturally formed on a surface thereof. Due to this, there are limits to high rate charging and discharging characteristics and cycle life. Since there is an increasing demand of industry for high voltage and high rate charging and discharging characteristics, it is necessary to improve these characteristics.

Further, in case of an electrode currently prepared by this method, there is a problem that a coated material is separated from an aluminum current collector with the passage of time due to insufficient adhesion between the current collector and an active material layer. Since a commonly used binder is non-conductive, there is a problem of deterioration of conductivity of the current collector. Further, there is a problem of deterioration of electrical conductivity of the current collector due to an oxide layer, a nonconductor, formed on a surface of aluminum when a high oxidation voltage is applied to the aluminum during charging and discharging.

### SUMMARY OF THE INVENTION

The present invention has been invented in order to overcome the above-described problems in a metal current collector of an electrochemical capacitor and it is, therefore, an object of the present invention to provide a metal current collector of an electrochemical capacitor capable of reducing electrical resistance between the current collector and an active material layer by increasing a contact area between the metal current collector and the active material layer.

Further, it is another object of the present invention to provide a method for preparing a metal current collector of an electrochemical capacitor.

Further, it is still another object of the present invention to provide a high output and high energy density electrochemical capacitor by increasing electrical resistance and a contact area between electrode active material layers using a metal current collector.

In accordance with one aspect of the present invention to achieve the object, there is provided a metal current collector including: a metal substrate having grooves on a surface thereof; a carbon buffer layer formed on the metal substrate; and a conductive layer formed on the carbon buffer layer.

The metal substrate may be at least one selected from the group consisting of aluminum, stainless steel, titanium, tantalum, niobium, copper, nickel, and alloys thereof.

Preferably, the metal substrate may be aluminum or an alloy thereof.

The metal substrate may have a sheet-like foil, etched foil, expanded metal, punched metal, net, or foam shape.

It is preferred that the grooves formed on the metal substrate have a depth of 1.0 to 5.0 μm.

It is preferred that an interval between the grooves is 5.0 to 10.0 μm.

It is preferred that the carbon buffer layer uses a carbon (C)-containing material.

The carbon buffer layer may be formed in a portion or all of an uneven portion between the grooves formed on the metal substrate.

It is preferred that the conductive layer uses at least one conductive carbon selected from the group consisting of super-p, graphite, cokes, activated carbon, and carbon black.

In accordance with another aspect of the present invention to achieve the object, there is provided a method for preparing a metal current collector including: a first step of forming grooves on a substrate of a metal substrate; a second step of removing a native oxide layer formed on the metal substrate; a third step of forming a carbon buffer layer on the metal substrate from which the native oxide layer is removed; and a fourth step of forming a conductive layer on the carbon buffer layer.

The grooves may be formed by etching and locally corroding the surface of the metal substrate.

The removal of the native oxide layer may be processed by at least one acid solution selected from the group consisting of phosphoric acid, sulfuric acid, nitric acid, hydrochloric acid, acetic acid, carbonic acid, trifluoroacetic acid, oxalic acid, hydrofluoric acid, boric acid, perchloric acid, hypochlorous acid, and mixtures thereof.

The removal of the native oxide layer may be processed by at least one alkaline solution selected from the group consisting of potassium hydroxide, sodium hydroxide, lithium hydroxide, ammonia, and mixtures thereof.

The carbon buffer layer may be formed by high temperature diffusion after ion implantation or carbon deposition.

Further, the present invention may provide an electrochemical capacitor comprising a metal current collector.

The metal current collector may be used in one or both selected from a cathode and/or an anode.

In addition, the present invention may provide an electrochemical capacitor comprising an electrode including an electrode active material in the metal current collector.

It is preferred that the electrode active material is at least one carbon material selected from the group consisting of activated carbon, carbon nanotube (CNT), graphite, carbon aerogel, polyacrylonitrile (PAN), carbon nanofiber (CNF), activated carbon nanofiber (ACNF), vapor grown carbon fiber (VGCF), and graphene.

Most preferably, the electrode active material may be activated carbon with a specific surface area of 1.500 to 3.000 m²/g.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a view showing a structure of a metal current collector in accordance with the present invention;

FIG. 2 is a view showing a process of preparing the metal current collector in accordance with the present invention; and

FIG. 3 is a schematic diagram of the process of preparing the metal current collector in accordance with the present invention.

### DETAILED DESCRIPTION OF THE PREFERABLE EMBODIMENTS

Hereinafter, the present invention will be described in detail.

Terms used herein are provided to explain embodiments, not limiting the present invention. Throughout this specification, the singular form includes the plural form unless the context clearly indicates otherwise. Further, terms “comprises” and/or “comprising” used herein specify the existence of described shapes, numbers, steps, operations, members, elements, and/or groups thereof, but do not preclude the existence or addition of one or more other shapes, numbers, operations, members, elements, and/or groups thereof.

The present invention relates to a metal current collector used in an electrochemical capacitor, a method for preparing the same, and electrochemical capacitors comprising the same.

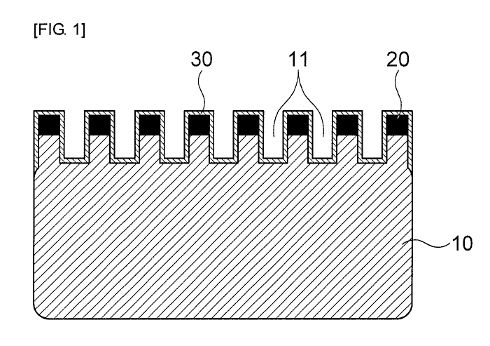

A metal current collector in accordance with an embodiment of the present invention is as shown in the following FIG. 1 and includes a metal substrate 10 having grooves 11 on a surface thereof, a carbon buffer layer 20 formed on the metal substrate 10, and a conductive layer 30 formed on the carbon buffer layer 20.

That is, when the surface of the metal substrate 10 is locally corroded, the grooves 11 are formed in the corroded portions to form a nanorod array so that a surface area of the current collector can be increased.

When the surface of the metal substrate 10 is locally corroded, it is possible to process along a triple junction line formed on the metal itself or to process by etching arbitrary points.

Although FIG. 1 shows that the groove 11 has a trench shape with a depth of about 2 to 5 μm, it shows one of various shapes, and the shape of the groove 11 is not particularly limited and may be, for example, a round column, a cone, and so on. This groove may have a predetermined shape by adjusting the kind, concentration, temperature, and so on of an etching solution used for corrosion.

It is preferred that an interval between the grooves formed on the metal substrate is 5.0 to 10.0 μm. When there is no specific condition such as a triple junction line, that is, in general case, acid concentration and process conditions should be severe in order to reduce the interval. In this case, process efficiency for preparation of a cell is deteriorated due to deterioration of mechanical properties of the current collector. On the contrary, when the interval is too large, an actual contact area between an electrode layer and the current collector is reduced and thus resistance is increased again.

The etching solution used at this time may be one selected from the group consisting of hydrochloric acid, phosphoric acid, fluosilicic acid, and sulfuric acid but not limited thereto.

Further, it is preferred that local corrosion is performed at a temperature of 50 to 90° C. in the aspect that a uniform etching pit is formed within a predetermined time in consideration of process efficiency but not particularly limited thereto.

By forming the grooves on the surface of the metal substrate as above, the surface area of the current collector is increased and thus the actual effective contact area with the electrode is increased so that contact resistance is reduced. Further, it is possible to improve charging and discharging speed by facilitating rapid diffusion of ions through adjustment of size of the well-aligned grooves 11.

The metal substrate used in the present invention may be at least one selected from the group consisting of aluminum, stainless steel, titanium, tantalum, niobium, copper, nickel, and alloys thereof, and among them, aluminum or an alloy thereof may be preferably used.

The metal substrate may have a sheet-like foil, etched foil, expanded metal, punched metal, net, or form shape, and the shape of the metal substrate is also not particularly limited.

Further, the metal current collector in accordance with the present invention includes the carbon buffer layer 20 formed on the metal substrate 10 having the grooves 11.

Typically, since metal such as aluminum is immediately oxidized when exposed to the air, a native oxide layer is formed on the metal substrate having the grooves. However, since this native oxide layer is an insulating layer, it increases electrical resistance between the current collector and an active material layer. Further, when the grooves are formed on the surface of the metal substrate, since it is not possible to exclude formation of the relatively thick native oxide layer along the grooves, electrical conductivity is reduced due to the native oxide layer, a nonconductor. Due to this, performance degradation is more remarkable in high voltage and high current.

Therefore, in the present invention, after removing the native oxide layer having a negative impact on electrical conductivity, the carbon buffer layer 20 is formed on the metal substrate 10.

The carbon buffer layer 20 artificially diffuses a carbon-containing material on the surface of the metal substrate, on which the grooves are formed, by methods such as ion implantation. As in the following FIG. 1, the carbon buffer layer 20 may be formed in a region surrounding a portion or all of an uneven portion between the grooves 11 formed on the metal substrate 10.

It is expected that some of ingredients of the metal substrate 10, which constitutes the metal current collector, and a carbon material coexisting in the carbon buffer layer 20 permeate into the uneven portion between the grooves. Therefore, since the carbon buffer layer 20 contains the same ingredients as the carbon material used as an electrode active material, it is possible to improve adhesive strength with the electrode active material layer.

Further, the metal current collector in accordance with the present invention includes the conductive layer 30 formed on the carbon buffer layer 20.

The conductive layer 30 maximizes rapid discharge of charged charges and reduces resistance on an interface between the current collector and the active material layer.

Therefore, since a specific surface area is large compared to an existing current collector which is simply surface-etched and the conductive layer is formed after removing an aluminum oxide layer, an obstacle to electrical conductivity, contact resistance occurring when the charged charges are discharged to the outside is very low.

It is preferred that a material of this conductive layer is a material with low electrical conductivity, for example, a material with electrical conductivity of higher than 10 S/m, preferably, higher than 100 S/m. This material may be, for example, at least one conductive carbon selected from the group consisting of super-p, graphite, cokes, activated carbon, and carbon black but not limited thereto.

The conductive layer 30 of the present invention is formed on the carbon buffer layer 20, and the carbon buffer layer 20 is formed on the metal substrate 10 having the grooves 11. Therefore, the conductive layer 30 may be formed in the same shape as the grooves formed on the surface of the metal substrate along the shape of the carbon buffer layer 20 and may be formed to be buried in the grooves as well as on the surface of the metal substrate. Therefore, a thickness of the conductive layer 30 is 1.0 to 5.0 μm from a surface of the groove of the metal substrate to maximize electrical conductivity while suppressing a reduction in capacitance per unit volume of an electrode. The smaller the thickness of the conductive layer is, the better it is, but when the thickness of the conductive layer is less than 1.0 μm, it is not preferable due to difficulty in a press process, but the thickness of the conductive layer is not particularly limited.

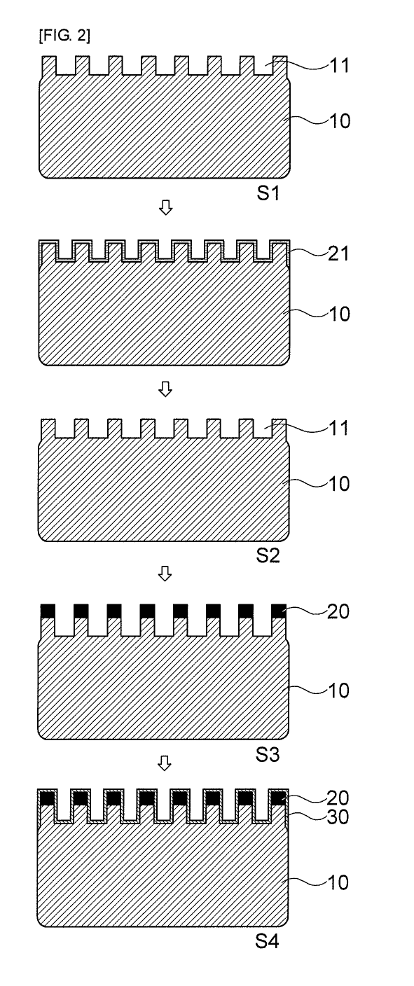

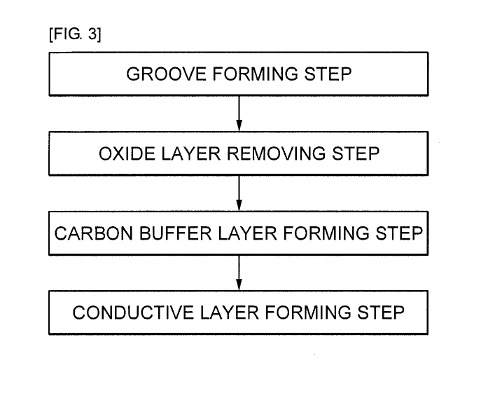

Hereinafter, a method for preparing a metal current collector in accordance with the present invention will be described in detail with reference to FIGS. 2 and 3.

A metal current collector in accordance with the present invention can be prepared by passing through a first step (S1) of forming grooves 11 on a surface of a metal substrate 10, a second step (S2) of removing a native oxide layer 21 formed on the metal substrate 10, a third step (S3) of forming a carbon buffer layer 20 on the metal substrate 10 from which the native oxide layer 21 is removed, and a fourth step (S4) of forming a conductive layer 30 on the carbon buffer layer 20.

First, the first step (S1) is a step of forming the grooves 11 by etching some points of the surface of the metal substrate 10 or locally corroding the metal substrate 10 along a triple junction line. Since the triple junction line is a unique characteristic of the metal substrate 10 used, when the metal substrate 10 is locally corroded along the line or etched along some points of the surface thereof, the grooves 11 are formed at regular intervals in the corroded and etched portions.

In the drawings of the present invention, the groove 11 is shown in a trench shape but may have an uneven shape, a cylindrical shape, and so on. The shape of the groove 11 is not particularly limited. The groove may have a predetermined shape by adjusting the kind, concentration, temperature, and so on of an etching solution used for corrosion.

Meanwhile, when the metal substrate 10 having grooves 11 is exposed to the air, the metal substrate 10 is easily oxidized due to its characteristics so that the thin native oxide layer 21 is formed on the surface of the metal substrate 10. The native oxide layer 21 is naturally formed when exposed to the air, not by an artificial external means. For example, when the metal substrate 10 is aluminum or an alloy thereof, the surface of the metal substrate 10 is naturally oxidized so that an aluminum oxide (Al₂O₃) is formed on the surface of the metal substrate 10.

However, since this native oxide layer 21 increases resistance between the metal current collector and an active material layer, in the present invention, a process of removing the native oxide layer 21 is performed as the second step (S2).

After passing through the process of removing the native oxide layer 21, it becomes a state of the metal substrate of the first step, on which the grooves are formed.

In accordance with an embodiment of the present invention, a chemical method of removing the native oxide layer 21 by immersing the native oxide layer 21 in an appropriate solution or an etching method may be used.

It is preferred that the solution used to remove the native oxide layer 21 may be, for example, at least one acid solution selected from the group consisting of phosphoric acid, sulfuric acid, nitric acid, hydrochloric acid, acetic acid, carbonic acid, trifluoroacetic acid, oxalic acid, hydrofluoric acid, boric acid, perchloric acid, hypochlorous acid, and mixtures thereof.

Further, in accordance with another embodiment of the present invention, the removal of the native oxide layer may use at least one alkaline solution selected from the group consisting of potassium hydroxide, sodium hydroxide, lithium hydroxide, ammonia, and mixtures thereof.

Further, when using an etching method, dry etching is more preferable, and for example, sputter etching may be performed by using various inert gas ions such as argon and nitrogen. However, the etching method is not limited to the sputter etching, and other etching methods can be used.

In the third step (S3), the carbon buffer layer 20 is formed on the metal substrate 10 from which the native oxide layer 21 is removed.

The carbon buffer layer 20 may be formed by methods such as high temperature diffusion of a carbon-containing material after ion implantation or carbon layer disposition, but the method of forming the carbon buffer layer 20 is not particularly limited.

The carbon buffer layer 20 may be formed in a region surrounding a portion or all of an uneven portion between the grooves 11 formed on the metal substrate 10. Further, some of ingredients of the metal substrate 10, which constitutes the metal current collector, and a carbon-containing material are mixed in the carbon buffer layer 20.

Finally, the step (S4) of forming the conductive layer 30 on the carbon buffer layer 20 is performed. A method of forming the conductive layer 30 is not particularly limited, and for example, physical vapor deposition (PVD) such as a sputtering method, an ion plating (IP) method, and an arc ion plating (AlP) method or chemical vapor deposition (CVD) such as a plasma CVD method may be used. Further, the conductive layer 30 may be formed by coating a conductive layer forming material after preparing the conductive layer forming material in the form of slurry.

In accordance with an embodiment of the present invention, it is preferred that the conductive layer 30 is formed with a thickness of 1.0 to 5.0 μm from an uppermost portion of the groove while filling a buried portion of the groove in order to completely cover the metal substrate 10 having the grooves 11.

Further, in accordance with another embodiment of the present invention, the conductive layer 30 may be formed in the same shape as the grooves 11 without being coated on the buried groove 11 region along the shape of the grooves 11.

It is preferred that a material for forming the conductive layer 30 is at least one conductive powder selected from the group consisting of super-p, graphite, cokes, activated carbon, and carbon black.

It is possible to reduce electrical resistance of the current collector and maximize rapid discharge of charged charges by forming the conductive layer 30.

Further, the present invention may provide an electrochemical capacitor comprising the metal current collector. The metal current collector may be used in one or both selected from a cathode and/or an anode.

An electrochemical capacitor in accordance with the present invention includes an electrode formed by coating an electrode active material slurry composition on the current collector, a separator, and an electrolyte.

The electrode active material slurry composition may be prepared by mixing and agitating an electrode active material, a conductive agent, a binder, a solvent, and other additives.

Preferably, the electrode active material in accordance with the present invention may be at least one carbon material selected from the group consisting of activated carbon, carbon nanotube (CNT), graphite, carbon aerogel, polyacrylonitrile (PAN), carbon nanofiber (CNF), activated carbon nanofiber (ACNF), vapor grown carbon fiber (VGCF), and graphene.

In accordance with a preferable embodiment of the present invention, it is most preferred that the electrode active material may be activated carbon with a specific surface area of 1.500 to 3.000 m²/g.

Further, the conductive agent may include conductive power such as super-p, ketjen black, acetylene black, carbon black, and graphite.

The binder may use, for example, at least one selected from fluorine resins such as polytetrafluoroethylene (PTFE) and polyvinylidenfluoride (PVDF); thermoplastic resins such as polyimide, polyamideimide, polyethylene (PE), and polypropylene (PP); cellulose resins such as carboxymethyl cellulose (CMC); rubber resins such as styrene-butadiene rubber (SBR); and mixtures thereof but not particularly limited thereto. It is fine to use all binder resins used in a typical electrochemical capacitor.

Further, the electrode is prepared by coating the electrode active material composition on the current collector prepared according to the present invention with a predetermined thickness, and a method of coating the electrode active material composition is not particularly limited.

Further, a mixture of the electrode active material, the conductive agent, and the solvent is formed into a sheet by the binder resin or a sheet extruded by extrusion is bonded to the current collector by a conductive adhesive.

The separator in accordance with the present invention may use all materials used in a conventional electric double layer capacitor or lithium ion battery, for example, a microporous film manufactured from at least one polymer selected from the group consisting of polyethylene (PE), polypropylene (PP), polyvinylidenfluoride (PVDF), polyvinylidene chloride, polyacrynitril (PAN), polyacrylamide (PAM), polytetrafluoroethylene (PTFE), polysulfone, polyether sulfone (PES), polycarbonate (PC), polyamide (PA), polyimide (PI), polyethyleneoxide (PEO), polypropylene oxide (PPO), cellulose polymer, and polyacrylic polymer. Further, a multilayer film manufactured by polymerizing the porous film may be used, and among them, the cellulose polymer may be preferably used.

It is preferred that a thickness of the separator is about 15 to 35 μm but not limited thereto.

The electrolyte of the present invention may be an organic electrolyte containing at least one selected from non-lithium salts such as TEABF₄ and TEMABF₄; spiro salts; and at least one lithium salt selected from the group consisting of LiPF₆, LiBF₄, LiCLO₄, LiN(CF₃SO₂)₂, CF₃SO₃Li, LiC(SO₂CF₃)₃, LiAsF₆, and LiSbF₆ but not limited thereto.

The solvent of the electrolyte may be at least one selected from the group consisting of acrylonitrile, ethylene carbonate, propylene carbonate, dimethyl carbonate, ethyl methyl carbonate, sulfolane, and dimethoxyethane but not limited thereto. It is preferred that concentration of an electrolyte salt in the electrolyte is 0.1 to 2.5 mol/L or 0.5 to 2.0 mol/L.

It is preferred that a case (exterior material) of the electrochemical capacitor of the present invention uses an aluminum-containing laminate film, which is typically used in a secondary battery and an electric double layer capacitor, but not particularly limited thereto.

Hereinafter, preferred embodiments of the present invention will be described in detail. The following embodiments merely illustrate the present invention, and it should not be interpreted that the scope of the present invention is limited to the following embodiments. Further, although certain compounds are used in the following embodiments, it is apparent to those skilled in the art that equal or similar effects are shown even when using their equivalents.

### Embodiment 1

### Preparation of Metal Current Collector

After preparing a plain aluminum foil with a thickness of 25 μm, ultrasonic cleaning is performed for each 20 minutes by sequentially using acetone and ethyl alcohol. The cleaned aluminum foil is treated with fluosilicic acid (H₂SiF₆) at 45° C. for 60 seconds to be locally corroded so that grooves are formed on a surface of the aluminum foil. The formed grooves have a depth of 1.0 to 5.0 μm, and an interval between the grooves is 5.0 to 10.0 μm.

Next, AC electrolytic etching is performed at 35° C. for 2 minutes in a mixture of 1.0M hydrochloric acid (HCl) and 0.01 M sulfuric acid (H₂SO₄) to remove a native oxide layer.

A carbon buffer layer is formed with a depth of 1.0 μm on the surface of the aluminum foil, from which the native oxide layer is removed, by using a C ion implantation apparatus. Next, a conductive layer is formed by coating conductive layer slurry on the carbon buffer layer using a comma coater after preparing the conductive layer slurry by mixing and agitating super-p 80 g, CMC 3.5 g and SBR 5.8 g as binders, and water 155 g.

After that, a current collector, on which an electrode is to be coated, is prepared by performing ultrasonic cleaning for each 20 minutes sequentially using acetone and ethyl alcohol again.

### Comparative Example 1

An etched aluminum foil with a thickness of 20 μm is used as a metal current collector.

### Embodiment 2, Comparative Example 2

### Preparation of Electrochemical Capacitor

### 1) Preparation of Electrode

Electrode active material slurry is prepared by mixing and agitating activated carbon (specific surface area 2150 m²/g) 85 g, super-p 18 g as a conductive agent, CMC 3.5 g, SBR 12.0 g, and PTFE 5.5 g as binders, and water 225 g.

The electrode active material slurry is coated on the metal current collector in accordance with the embodiment 1 and the comparative example 1 by a comma coater, temporarily dried, and cut to an electrode size of 50 mm×100 mm. A cross-sectional thickness of the electrode is 60 μm. Before assembly of a cell, the electrode is dried in a vacuum at 120° C. for 48 hours.

### 2) Preparation of Electrolyte

An electrolyte is prepared by dissolving a spiro salt in an acrylonitrile solvent so that concentration of the spiro salt is 1.3 mol/L.

### 3) Assembly of Capacitor Cell

The prepared electrodes (cathode, anode) are immersed in the electrolyte with a separator (TF4035 from NKK, cellulose separator) interposed therebetween and put in a laminate film case to be sealed.

### Experimental Example

### Estimation of Capacity of Electrochemical Capacitor Cell

Capacity of the last cycle is measured by charging a cell to 2.5V at a constant current with a current density of 1 mA/cm² and discharging the cell at a constant current of 1 mA/cm² three times after 30 minutes under the condition of a constant temperature of 25° C., and measurement results are shown in the following table 1.

Further, resistance characteristics of each cell are measured by an ampere-ohm meter and an impedance spectroscopy, and measurement results are shown in the following table 1.

TABLE 1

| | | Resistance (AC ESR, |
|---|---|---|
| Classification | Initial Capacity (F) | mΩ) |
| Comparative Example 2 | 10.55 | 19.11 |
| Embodiment 2 | 12.78 | 14.73 |

As in the results of the table 1, capacity of the comparative example 2, which is an electrochemical capacitor (EDLC cell) including an electrode using a typically used current collector, is 10.55F and at this time, a resistance value is 19.11 mΩ.

On the other hand, capacity of the embodiment 2, which is an electrochemical capacitor (EDLC cell) including an electrode using a metal current collector including a metal substrate having grooves formed by surface treatment of the current collector, a carbon buffer layer formed on the metal substrate, and a conductive layer formed on the metal substrate like the present invention, is 12.78F and at this time, a resistance value is 14.73 mΩ.

From these results, it is possible to prepare an electrode capable of reducing resistance per unit volume of a cell and increasing capacity of the cell through surface modification of a current collector as above.

According to the present invention, a metal current collector including a metal substrate having grooves on a surface thereof, a carbon buffer layer formed on the metal substrate, and a conductive layer has high adhesive strength and low contact resistance.

Therefore, an electrode manufactured from the metal current collector has a low ESR value and an electrochemical capacitor including the same can perform high rate charging and discharging at a high voltage to increase a cycle life. Further, it is possible to satisfy mechanical characteristics such as adhesive strength and durability by forming the conductive buffer layer at the same time.

What is claimed is:

1. A metal current collector comprising:
a metal substrate having grooves on a surface thereof;
a carbon buffer layer formed on the metal substrate having the grooves; and
a conductive layer formed on the carbon buffer layer.

2. The metal current collector according to claim 1, wherein the metal substrate is at least one selected from the group consisting of aluminum, stainless steel, titanium, tantalum, niobium, copper, nickel, and alloys thereof.

3. The metal current collector according to claim 1, wherein the metal substrate is aluminum or an alloy thereof.

4. The metal current collector according to claim 1, wherein the metal substrate has one structure selected from a sheet-like foil structure, an etched foil structure, an expanded metal structure, a punched metal structure, a net structure, and a foam structure.

5. The metal current collector according to claim 1, wherein the grooves formed on the metal substrate have a depth of 1.0 to 5.0 μm.

6. The metal current collector according to claim 1, wherein an interval between the grooves formed on the metal substrate is 5.0 to 10.0 μm.

7. The metal current collector according to claim 1, wherein the carbon buffer layer uses a carbon (C)-containing material.

8. The metal current collector according to claim 1, wherein the carbon buffer layer is formed in a portion or all of an uneven portion between the grooves formed on the metal substrate.

9. The metal current collector according to claim 1, wherein the conductive layer uses at least one conductive carbon selected from the group consisting of super-p, graphite, cokes, activated carbon, and carbon black.

10. A method for preparing a metal current collector comprising:
a first step of forming grooves on a surface of a metal substrate;
a second step of removing a native oxide layer formed on the metal substrate;
a third step of forming a carbon buffer layer on the metal substrate from which the native oxide layer is removed; and
a fourth step of forming a conductive layer on the carbon buffer layer.

11. The method for preparing a metal current collector according to claim 10, wherein the grooves are formed by etching and locally corroding the surface of the metal substrate.

12. The method for preparing a metal current collector according to claim 10, wherein the removal of the native oxide layer is processed by at least one acid solution selected from the group consisting of phosphoric acid, sulfuric acid, nitric acid, hydrochloric acid, acetic acid, carbonic acid, trifluoroacetic acid, oxalic acid, hydrofluoric acid, boric acid, perchloric acid, hypochlorous acid, and mixtures thereof.

13. The method for preparing a metal current collector according to claim 10, wherein the removal of the native oxide layer is processed by at least one alkaline solution selected from the group consisting of potassium hydroxide, sodium hydroxide, lithium hydroxide, ammonia, and mixtures thereof.

14. The method for preparing a metal current collector according to claim 10, wherein the carbon buffer layer is formed by high temperature diffusion after ion implantation or carbon deposition.

15. An electrochemical capacitor comprising a metal current collector according to claim 1.

16. The electrochemical capacitor according to claim 15, wherein the metal current collector is used in one or both selected from a cathode and/or an anode.

17. An electrochemical capacitor comprising an electrode including an electrode active material in a metal current collector according to claim 1.

18. The electrochemical capacitor according to claim 17, wherein the electrode active material is at least one carbon material selected from the group consisting of activated carbon, carbon nanotube (CNT), graphite, carbon aerogel, polyacrylonitrile (PAN), carbon nanofiber (CNF), activated carbon nanofiber (ACNF), vapor grown carbon fiber (VGCF), and graphene.

19. The electrochemical capacitor according to claim 17, wherein the electrode active material is activated carbon with a specific surface area of 1.500 to 3.000 m²/g.
